(19) United States
(12) Patent Application Publication
(10) Pub. No.: US 2019/0112711 A1
(43) Pub. Date: Apr. 18, 2019

(54) Roll-To-Roll Atomic Layer Deposition Apparatus and Method

(71) Applicant: 3M INNOVATIVE PROPERTIES COMPANY, St. Paul, MN (US)

(72) Inventors: Christopher S. Lyons, St. Paul, MN (US); Bill H. Dodge, Finlayson, MN (US); Joseph C. Spagnola, Woodbury, MN (US); Glen A. Jerry, Blaine, MN (US); Ameeta R. Goyal, Woodbury, MN (US); Ronald P. Swanson, Woodbury, MN (US); James N. Dobbs, Woodbury, MN (US)

(21) Appl. No.: 16/090,516

(22) PCT Filed: Mar. 24, 2017
(86) PCT No.: PCT/US2017/024096

§ 371 Date: Oct. 1, 2018

Related U.S. Application Data
(60) Provisional application No. 62/316,886, filed on Apr. 1, 2016.

(51) Int. Cl. C23C 16/54; C23C 16/455; C23C 16/02

(52) U.S. Cl. CPC C23C 16/545; C23C 16/45536; C23C 16/02; C23C 16/45544

(57) ABSTRACT

A method is provided. The method may include engaging a first edge region on a first surface of a substrate with a first support roller; engaging a second edge region on the first surface of the substrate with a second support roller; transporting the substrate over the first and the second support rollers; repeating the following sequence of steps to form a thin film on the substrate: (a) exposing the substrate to a first precursor; (b) supplying a reactive species to the substrate after exposing the substrate to the first precursor; and depositing a vapor on the thin film to form a coating on the thin film.

### BACKGROUND

Gases, liquids, and other environmental factors may cause deterioration of various goods, such as food, medical, electrical devices, and pharmaceutical products. Barrier films have been included on or within the packaging associated with sensitive goods to prevent or limit the permeation of gases or liquids, such as oxygen and water, through the packaging during manufacturing, storage, or use of the goods. For example, flexible barrier-coated polymer films have been used for electronic devices whose components are sensitive to the ingress of water vapor and oxygen. Market applications for barrier film technology include, for example, flexible thin film and organic photovoltaic solar cells, organic light emitting diodes (OLED) used in displays and solid state lighting and other luminescent devices including quantum dots. Atomic layer deposition (“ALD”), formerly known as atomic layer epitaxy (“ALE”), is a thin film deposition process that is known for use in manufacturing electroluminescent (EL) display panels, in semiconductor integrated circuit manufacturing, and for other purposes. A barrier film provides advantages over glass as it is flexible, light-weight, durable, and enables low cost continuous roll-to-roll processing. While the preparation of barrier layers effective against the penetration of air and moisture are known, there are needs for a better process and system to make the barrier film.

### SUMMARY

The present disclosure relates to a roll-to-roll ALD system and a method of making a barrier film. The system and method of the current disclosure can enable a very high speed depositions on a wide variety of substrates and maintain barrier film's performance through wind-up and subsequent post processing.

In a first aspect, a method is provided. The method may include engaging a first edge region on a first surface of a substrate with a first support roller, wherein the first support roller is rotatable on a first end of a shaft, and wherein the web material has a length substantially greater than the width thereof; engaging a second edge region on the first surface of the substrate with a second support roller, wherein the second support roller is rotatable on a second end of the shaft opposite the first end thereof, and wherein a central region between the first roller and the second roller and comprising at least about 50% of a width of the substrate is free of support from a roller; transporting the substrate over the first and the second support rollers; repeating the following sequence of steps for a number of times sufficient to form a thin film on the substrate: (a) exposing the substrate to a first precursor; (b) supplying a reactive species to the substrate to react with the first precursor after exposing the substrate to the first precursor; wherein the thin film is formed as a reaction product of the first precursor with the reactive species; and depositing a vapor on the thin film to form a coating on the thin film.

In another aspect, a system is provide. The system may include a first zone into which a first precursor is introduced; a second zone into which a second precursor is introduced; a third zone between the first zone and the second zone and in which a reactive species is generated; a substrate transport mechanism, comprising: at least two support rollers contacting a single major surface of the substrate, wherein the substrate has a first and a second edge, the support rollers comprising: a first support roller contacting a first edge region of the substrate, and a second support roller contacting a second edge region of the substrate, wherein the substrate includes an un-contacted region between the first and the second support roller including at least about 50% of the width of the substrate; and a vapor processing system comprising a vapor source for producing a vapor.

The above summary is not intended to describe each disclosed embodiment or every implementation of the present disclosure. The figures and the detailed description below more particularly exemplify illustrative embodiments.

### BRIEF DESCRIPTION OF THE DRAWINGS

Throughout the specification reference is made to the appended drawings, where like reference numerals designate like elements, and wherein:

FIG. 1 shows a schematic cross-sectional view of one embodiment, illustrating a system and method for roll-to-roll ALD;

FIG. 2 shows a schematic overhead view of an embodiment of a substrate transport mechanism.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

For the following Glossary of defined terms, these definitions shall be applied for the entire application, unless a different definition is provided in the claims or elsewhere in the specification.

### Glossary

Certain terms are used throughout the description and the claims that, while for the most part are well known, may require some explanation. It should understood that:

The terms “about” or “approximately” with reference to a numerical value or a shape means+/−five percent of the numerical value or property or characteristic, but expressly includes the exact numerical value. For example, a viscosity of “about” 1 Pa-sec refers to a viscosity from 0.95 to 1.05 Pa-sec, but also expressly includes a viscosity of exactly 1 Pa-sec.

The term “substantially” with reference to a property or characteristic means that the property or characteristic is exhibited to a greater extent than the opposite of that property or characteristic is exhibited. For example, a substrate that is “substantially” transparent refers to a substrate that transmits more radiation (e.g. visible light) than it fails to transmit (e.g. absorbs and reflects). Thus, a substrate that transmits more than 50% of the visible light incident upon its surface is substantially transparent, but a substrate that transmits 50% or less of the visible light incident upon its surface is not substantially transparent.

As used in this specification, the recitation of numerical ranges by endpoints includes all numbers subsumed within that range (e.g. 1 to 5 includes 1, 1.5, 2, 2.75, 3, 3.8, 4, and 5).

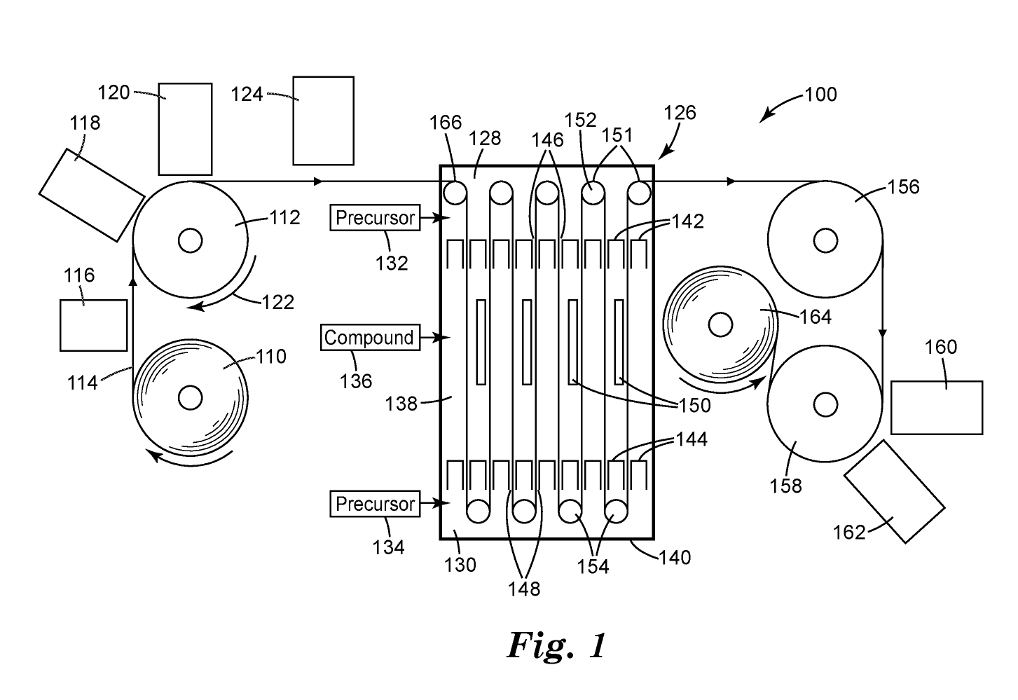

FIG. 1 is a diagram of a system 100, illustrating a process for making a barrier film. System 100 can be contained within an inert environment and can include an unwinder roller 110 for paying out a substrate 114 from an input roll of the substrate 114 and chilled drum 112 for receiving and moving providing a moving web. A substrate pretreating source 116 can provide a treatment of the surface the substrate 114, for example, supplying a plasma to substrate 114. A vapor processing system 118 includes a vapor source for producing a vapor and depositing the vapor on substrate 114, as substrate 114 is passed over chilled drum 112. A vapor can be deposited on the substrate 114 to form a coating on a first surface of the substrate 114, as substrate 114 is passed over chilled drum 112. The chilled drum 112 may be provided with a cooling system, for example, a heat transfer fluid circulation such that at least the surface of chilled drum 112 is temperature controlled, thereby promoting condensation, reaction, and/or other form of deposition of vapor onto the substrate 114. In some embodiments, system 100 may further include one or more curing sources 120. Curing sources 120 can initiate polymerization of a liquid monomer or a liquid oligomer deposited from the vapor onto the substrate. Curing sources 120 useful in the systems of the present disclosure include one or more of, for example, heat sources, ultraviolet radiation sources, e-beam radiation sources, and plasma radiation sources. The vapor coating deposited on substrate 114 can be cured by curing sources 120 to form a base polymer layer on the substrate 114, as chilled drum 112 advances the substrate 114 in a direction shown by arrow 122. In some embodiments, system 100 may further include a heating system 124 to heat the substrate 114 before the ALD deposition of a thin film onto the substrate. Heating system 124 useful in the systems of the present disclosure include one or more of, for example, an infrared radiation heating source, a heated drum, a conductive heating source and inductive heaters. In some embodiments, the substrate 114 can be heated to a range of 50 to 150° C. In some embodiments, the substrate 114 can be heated to a range of 70 to 100° C. In some embodiments, the substrate 114 can be heated to 100° C. In some embodiments, the substrate 114 can be heated to 80° C.

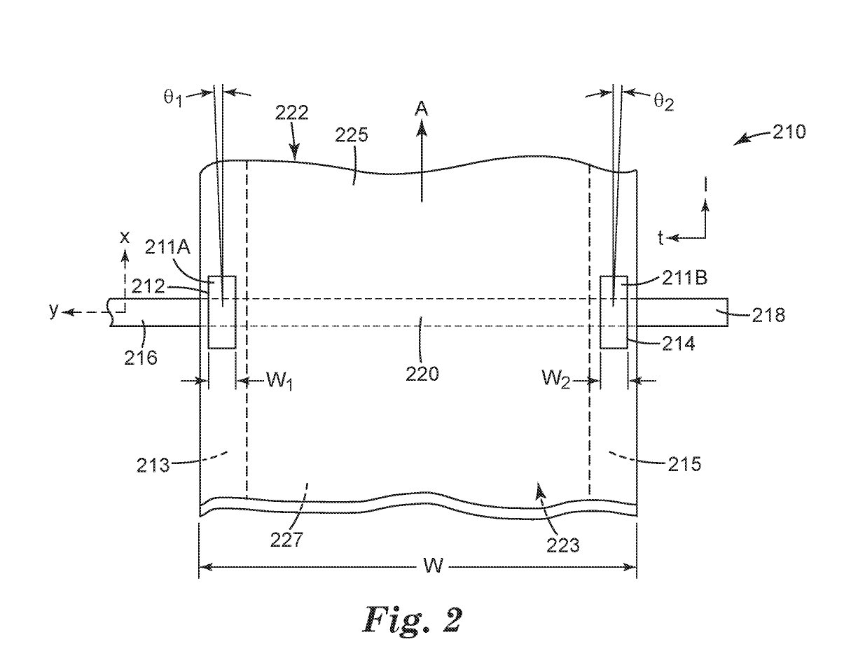

After the substrate 114 is heated, the substrate 114 is advanced into an ALD coating system 126 for the deposition a thin film onto the substrate 114. With reference to FIG. 2, ALD coating system 126 includes first and second precursor zones 128, 130, respectively, separated by a third zone 138 in which a reactive species is generated. When in use, reactive first and second precursor gases (Precursor 1 and Precursor 2) are introduced into the respective first and second precursor zones 128, 130 from first and second precursor delivery systems 132, 134. Precursor delivery systems 132, 134 may include precursor source containers (not shown) located outside or within precursor zones 128, 130. Additionally or alternatively, precursor delivery systems 132, 134 may include piping, pumps, valves, tanks, and other associated equipment for supplying precursor gases into precursor zones 128, 130. A compound delivery system 136 is similarly included for injecting a compound into a third zone 138 to generate reactive species.

In the embodiment shown in FIG. 1, precursor zones 128, 130 and third zone 138 are defined and bordered by an outer reaction chamber housing or vessel 140, divided by first and second dividers 142, 144. In other embodiments, ALD coating system 126 may include additional zones, for example, an isolation zone between precursor zone 128 and zone 138 and an isolation zone between precursor zone 130 and zone 138. A series of first passageways 146 through first divider 142 are spaced apart along a general direction of travel of substrate 114, and a corresponding series of second passageways 148 are provided through second divider 144. The passageways 146, 148 are arranged and configured for substrate 114 to be threaded therethrough back and forth between first and second precursor zones 128, 130 multiple times, and each time through the third zone 138. For a web substrate, passageways 146, 148 preferably comprise slits having a width (exaggerated in FIG. 1) that is slightly greater than the thickness of substrate 114 and a length (not shown) extending into the plane of FIG. 1 (i.e., normal to the page) and that is slightly greater than a width of the substrate. The third zone 138 is, thus, preferably separated (albeit imperfectly) from the first precursor zone 128 by first divider 142 and from second precursor zone 130 by second divider 144.

A series of plasma or other free radical-generating generators 150 is operably associated with third zone 138, wherein the free radical generators 150 operating at 150 W to 1500 W generate reactive species from the compound 136. Radical generators 150 may include a radio-frequency (RF) plasma generator, microwave plasma generator direct-current (DC) plasma generator, or UV light source, and preferably continuously generates a population of radical species in-situ within third zone 138 by means of a plasma, for example. In some embodiments, radical generators 150 are positioned in third zone 138 so that only one surface of substrate 114 may contact reactive species. Reactive species can include, but is not limited to, activated oxygen, ozone, water, activated nitrogen, ammonia and activated hydrogen. In some embodiments, reactive species can be generated by applying energy to chemical compound 136, for example, cracking a dry, oxygen-containing compound so as to generate the activated oxygen species. In some of such embodiments, a plasma generator (e.g., a DC plasma source, an RF plasma source, or an inductively-coupled plasma source) may energize and decompose a dry gaseous oxygen-containing compound (for example dry air, O₂, CO₂, CO, NO, NO₂, or mixtures of two or more of the foregoing, with or without added nitrogen (N₂) and/or another suitable inert carrier gas). In some other embodiments, an oxygen-containing compound, for example, hydrogen peroxide, water, or a mixture thereof, may be decomposed or cracked via non-plasma activation a thermal process). In still other embodiments, ozone may be generated (e.g., via corona discharge) remotely or proximal to the substrate or substrate path so that ozone is supplied to the substrate surface. In some embodiments, reactive species can be generated by introducing a chemical compound into a plasma.

In some embodiments, a first precursor is supplied into precursor zone 128. As the substrate 114 enters the first precursor zone 128, a surface 166 of the substrate 114 is exposed to the first precursor 132 so that the first precursor 132 is chemisorbed to the substrate surface, leaving a chemisorbed species at the surface that is reactive with reactive species. Following deposition of the first precursor on the substrate 114, the substrate 114 then enters the third zone 138, which in some embodiments is supplied reactive species generated in a plasma formed from compound 136. A second precursor enters precursor zone 130. The substrate 114 enters precursor zone 130 and is exposed to the second precursor. The substrate 114 then traverses the third zone 138 and precursor zone 128 a predetermined number of additional times before a thin film is formed on the substrate 114. In some embodiments, the substrate 114 then traverses the third zone 138 and precursor zone 128 between 2 or more additional times to form a thin film substrate 114. In some embodiments, the substrate 114 then traverses the third zone 138 and precursor zone 128 between 2 to 5 additional times to form a thin film substrate 114. In some embodiments, the thin film may have a thickness of no more than 100 nm, no more than 80 nm, no more than 60 nm, no more than 50 nm, no more than 30 nm, or no more than 20 nm. In some embodiments, the thin film may have a thickness of at least 1 nm, at least 3 nm, at least 5 nm or at least 10 nm. In some embodiments, the thin film may have a thickness of 1 nm to 100 nm, 3 nm to 80 nm, 3 nm to 60 nm, 3 nm to 50 nm, 3 nm to 30 nm, or 3 nm to 20 nm.

A substrate transport mechanism 151 of system 100 includes a carriage comprising multiple turning guides for guiding substrate 114, including a set of first support roller 152 and a set of second support roller 152a (not shown in FIG. 1) spaced apart along precursor zone 128. Substrate transport mechanism 150 may further include a set of idler rollers 154 that can be used to support the substrate during a change in the direction of motion of the substrate 114.

System 100 may further include a substrate cooling system 156 to cool the substrate after the substrate 114 exits ALD coating system 126. System 100 may further include chilled drum 158 for receiving and moving cooled substrate 114. An additional vapor processing system 160 can be included in system 100, includes a vapor source for producing a vapor and depositing the vapor onto the thin film that is formed on the surface 166 of the substrate 114, as substrate 114 is passed over chilled drum 158. The chilled drum 158 may be provided with a substrate cooling system, for example, a heat transfer fluid circulation such that at least the surface of chilled drum 158 is temperature controlled, thereby promoting condensation, reaction, and/or other form of deposition of vapor onto the substrate 114. In some embodiments, system 100 may further include one or more curing sources 162. Curing sources 162 can initiate polymerization of a liquid monomer or oligomer deposited from the vapor onto the thin film to form a coating. System 100 can include a winder roller 164 for receiving coated substrate 114 and coiling the substrate 114 into a take-up roll.

Referring to FIG. 2, a schematic overhead view of substrate transport mechanism 210 includes at least two support rollers 212, 214 that rotate about their respective shafts 216, 218. In various embodiments, the support rollers 212, 214 may turn on roller bearings on the shafts 216, 218, or may be driven on the shafts 216, 218. In some embodiments, the rollers may rotate about a single shaft 220. At least one of the support rollers 212, 214 in substrate transport mechanism 210 is “toed outward” and positioned at an angle θ in a plane x-y with respect to a direction x normal to a longitudinal axis y of the shafts 216, 218. In the embodiment of FIG. 2, the roller 212 is angled at an angle θ₁ and the roller 214 is angled at an angle θ₂ with respect to the direction x of motion of the substrate 222. In various embodiments, it is not necessary that θ₁=θ₂, and θ₁ and θ₂ can be independently selected from greater than about 0° to about 6°, or greater than about 0 to about 2°, or greater than about 0° to about 1°, or about 0.2° to about 0.8°.

A substrate 222 with a length 1 substantially longer than its width w moves along its length l in the direction of arrow A and traverses the support rollers 212, 214. The support rollers 212, 214 have widths w₁, w2 that are each substantially smaller than the width w of the substrate 222. In the embodiment of FIG. 2, the support rollers 212, 214 contact a first surface 223 of the substrate 222, but in other embodiments may contact a second surface 225 opposed to the first surface 223 of the substrate 222. In some embodiments, the support rollers 212, 214 may contact both sides 223, 225 of the substrate 222. The surfaces 211A, 211B of the support rollers 212, 214 contacting the substrate 222 can be independently selected from a wide range of materials including, but not limited to, natural and synthetic rubber, silicone, polymeric materials, metals, and the like. In some embodiments, the surfaces 211A, 211B of the support rollers 212, 214 can include o-rings or sleeves to modify the coefficient of static friction at an interface with the substrate 222.

The support rollers 212, 214 contact at least a portion of opposed edges 213, 215 of the first surface 223 of the substrate 222. A center region 227 of the first surface 223 of the substrate 222 does not contact the support rollers 12, 14 and remains unsupported by any roller. In various embodiments, the opposed edges 213, 215 of the substrate 222 can be independently selected to be substantially the same width as the support rollers 212, 214 and, depending on the intended application, can be substantially wider. In various embodiments, the center region of the first surface 223 of the substrate 222 is about 50% to about 98% of the width w of the substrate 222, or about 70% to about 95%, or about 80% to about 90%, of the width w. While not wishing to be bound by any theory, presently available evidence indicates that the toed outward orientation of at least one of the rollers gently pulls the substrate 222 in a transverse direction t normal to its length l, which maintains tension in the substrate 222 and helps to maintain sufficient engagement between the support rollers 212, 214 and the opposed edges 213, 215 to transport the substrate 222.

Suitable substrates 114 for use in the system and method described herein include flexible materials capable of roll-to-roll processing, such as paper, polymeric materials, metal foils, and combinations thereof. Suitable polymeric substrates include various polyolefins, e.g. polypropylene, various polyesters (e.g. polyethylene terephthalate, fluorene polyester), polymethylmethacrylate and other polymers such as polyethylene naphthalate, polycarbonate, polymethylmethacrylate, polyethersulphone, polyestercarbonate, polyetherimide, polyarylate, polyimide, vinyls, cellulose acetates, and fluoropolymers.

Suitable first precursor 132 and second precursor 134 can include those described in U.S. Pub. No. 2014/0242736. Non-limiting examples of first precursor 132 can include non-hydroxylated silicon-containing precursors including compounds such as tris(dimethylamino)silane (SiH[N(CH₃)₂]₃); tetra(dimethylamino)silane (Si[N(CH₃)₂]₄; bis(tertiary-butylamino)silane (SiH₂[HNC(CH₃)₃]₂); trisilylamine ((SiH₃)₃N) (available under the trade name TSA from L'Air Liquide S.A.); silanediamine, N,N′,N′-tetraethyl (SiH₂[N(C₂H₅)₂]₂) (available under the trade name SAM.24™ from L'Air Liquide S.A.); and hexakis(ethylamino)disilane (Si₂(NHC₂H₅)₆) (available under the trade name AHEAD™ from L'Air Liquide S.A.). Non-limiting examples of second precursor 134 can include metal-containing precursors, for example, metal halide compounds (e.g., titanium tetrachloride, tetrakis(dimethyamino)tin(TDMASn), zirconium tert-butoxide, Titanium Tetraisopropoxide, or TiCl₄) and metalorganic compounds (e.g., diethylzinc ((DEZ) or Zn(C₂H₅)₂) and trimethylaluminum (TMA)).

In some embodiments, vapor source of vapor processing system 118 and 160 may be configured as any device capable of vaporizing liquid. Suitable vapor sources may include, for example, heated baths, bubblers, atomizers, cyclone evaporators, ultrasonic evaporators, wiped-film evaporators, rolled film evaporators, spinning disk evaporators, rotary evaporators, porous frit evaporators, tubular evaporators, and the like. In various embodiments, the vapor source may include one or more of the vapor sources described in the following patents and publications, incorporated by reference herein in their entireties: U.S. Pub. No. 2008/0108180 (Charles, et al.); U.S. Pat. No. 8,658,248 (Anderson, et al.); U.S. Pat. No. 7,300,538 (Lemme et al.); U.S. Pat. No. 6,245,150 (Lyons et al.); U.S. Pat. No. 4,954,371 (Yializis et al.); U.S. Pat. No. 5,653,813 (Benzing et al.); U.S. Pat. No. 5,595,603 (Klinedinst et al.); U.S. Pat. No. 5,536,323 (Kirlin et al.); U.S. Pat. No. 5,431,736 (Boer et al.); U.S. Pat. No. 5,356,451 (Cain et al.); U.S. Pat. No. 5,558,687 (Cain et al.); U.S. Pat. No. 5,951,923 (Horie et al.); U.S. Pub. No. 2008/0017110 (Kim et al.); U.S. Pub. No. 2007/0120275 (Liu et al.); U.S. Pat. No. 6,089,548 (Plitzner et al.); U.S. Pat. No. 6,157,774 (Komino et al.); U.S. Pat. No. 6,958,107 (Clarke et al.); U.S. Pat. No. 6,409,839 (Sun et al.); and U.S. Pat. No. 6,488,985 (Honda et al.). While the present disclosure is described with respect to a single vapor source, it is to be appreciated that any number of additional vapor sources may be utilized. For example, a plurality of vapor sources may be useful in embodiments in which a vapor mixture is desired and vaporization of two or more components of the vapor mixture in a single vapor source is difficult or impracticable (e.g., due to varying vapor pressure curves, immiscibility of the components in a liquid state, or undesirable reactions of components in liquid state).

In illustrative embodiments, the vapor supplied by the vapor source may include monomers, oligomers, resins, waxes, solvents, organic compounds, organometallic compounds, metallic compounds, biologically active materials, and combinations thereof. Other suitable materials for vaporization include, but are not limited to, epoxies, vinyl ethers, (meth)acrylates, fluoro-containing polymers, styrene containing polymers, acetylenes, polyamides, acrylamides, parylenes, waxes, fluoropolyethers, polyamines, diallyldiphenylsilanes, metal alkoxides, metal alkyls, silicones, oils, dyes, proteins, peptides, polypeptides, lipids, carbohydrates, enzymes, nucleic acids, polynucleic acids, drugs, drug metabolites, and combinations thereof.

In various embodiments, the vapor supplied by the vapor source (and/or liquids or solids supplied as inputs to the vapor source) may include one or more additives to affect processing of the vapor and/or the properties and performance of a condensed or deposited material formed from the vapor, as is known in the art. For example, one or more additives may be included to lower surface tension, reduce viscosity, inhibit thermally-induced reactions such as polymerization, prevent oxidation reactions, or combinations thereof. To impart desirable properties in a condensed or deposited material formed from the vapor supplied by the vapor source, one or more additives may be included to absorb radiation (e.g., UV, visible wavelengths, IR, and microwave energy) and/or initiate reactions (e.g., photoinitiators, thermal initiators, and the like). Other additives may include colorants, crosslinkers, or other materials known in the art.

Following are a list of embodiments of the present disclosure.

1. A method comprising:

engaging a first edge region on a first surface of a substrate with a first support roller, wherein the first support roller is rotatable on a first end of a shaft, and wherein the substrate has a length substantially greater than a width thereof;

engaging a second edge region on the first surface of the substrate with a second support roller, wherein the second support roller is rotatable on a second end of the shaft opposite the first end thereof, and wherein a central region between the first roller and the second roller and comprising at least about 50% of a width of the substrate is free of support from a roller;

transporting the substrate over the first and the second support rollers;

repeating the following sequence of steps for a number of times sufficient to form a thin film on the substrate:
(a) exposing the substrate to a first precursor;
(b) supplying a reactive species to the substrate to react with the first precursor after exposing the substrate to the first precursor; wherein the thin film is formed as a reaction product of the first precursor with the reactive species; and

depositing a vapor on the thin film to form a coating on the thin film.

2. The method of embodiment 1, further comprising cooling the substrate before depositing the vapor on the thin film.
3. The method of any one of embodiments 1 to 2, comprising heating the substrate before exposing the substrate to the first precursor.
4. The method of any one of embodiments 1 to 3, comprising heating the substrate to a range of 50 to 150° C. before exposing the substrate to the first precursor.
5. The method of any one of embodiments 1 to 4, comprising heating the substrate to a range of 70 to 100° C. before exposing the substrate to the first precursor.
6. The method of any one of embodiments 1 to 5, wherein a second surface of the substrate opposite the first surface thereof does not substantially contact the reactive species.
7. The method of any one of embodiments 1 to 6, wherein depositing the vapor on the thin film occurs before the thin film contacts a solid surface covering more than 50% of the width of the substrate.
8. The method of any one of embodiments 1 to 7, wherein the thin film has a thickness of 1 nm to 100 nm.
9. The method of any one of embodiments 1 to 8, wherein the thin film has a thickness of 3 nm to 80 nm.
10. The method of any one of embodiments 1 to 9, wherein the thin film has a thickness of 3 nm to 20 nm.
11. The method of any one of embodiments 1 to 10, wherein the repeating step further comprises (c) after step (b), exposing the substrate to a second precursor and (d) supplying a reactive species to the substrate after exposing the substrate to the second precursor.
12. The method of any one of embodiments 1 to 11, further comprising orienting at least one of the support rollers at an angle relative to the direction of motion of the substrate.
13. The method of any one of embodiments 1 to 12, wherein the reactive species is generated by applying energy to a chemical compound.
14. The method of any one of embodiments 1 to 13, wherein the reactive species is generated by introducing a chemical compound into a plasma.
15. The method of any one of embodiments 1 to 14, wherein the thin film is deposited by atomic layer deposition.
16. The method of embodiment 15, further comprising depositing a vapor on the substrate to form a coating on the first surface of the substrate before the thin film is deposited.
17. The method of any one of embodiments 1 to 16, further comprising pretreating the first surface of the substrate by supplying a plasma before depositing the vapor on the substrate.
18. The method of any one of embodiments 1 to 17, further comprising curing the coating on the thin film or the first surface of the substrate.
19. The method of any one of embodiment 11, wherein the first and second precursor are same.
20. The method of any one of embodiment 11, wherein the first and second precursor are different.
21. A system, comprising,

a first zone into which a first precursor is introduced;

a second zone into which a second precursor is introduced;

a third zone between the first zone and the second zone and in which a reactive species is generated;

a substrate transport mechanism, comprising: at least two support rollers contacting a single major surface of the substrate, wherein the substrate has a first and a second edge, the support rollers comprising:
a first support roller contacting a first edge region of the substrate, and
a second support roller contacting a second edge region of the substrate,

wherein the substrate comprises an un-contacted region between the first and the second support roller comprising at least about 50% of the width of the substrate; and

a vapor processing system comprising a vapor source for producing a vapor.

22. The system of embodiment 21, further comprising a heating system to heat the substrate.
23. The system of any one of embodiments 21 to 22, further comprising a cooling system to cool the substrate.
24. The system of any one of embodiments 21 to 23, further comprising a curing source configured for initiating polymerization of a liquid monomer or a liquid oligomer deposited from the vapor onto the substrate.
25. The system of any one of embodiments 21 to 24, further comprising a free radical generator for supplying a reactive species to the third zone.
26. The system of any one of embodiments 21 to 25, further comprising an idler roller to support the substrate during a change in a direction of motion of the substrate.
27. The system of any one of embodiments 21 to 26, wherein at least one of the first support roller and the second support roller are angled with respect to the direction of motion of the substrate.

Unless otherwise indicated, all numbers expressing feature sizes, amounts, and physical properties used in the specification and claims are to be understood as being modified by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

All references and publications cited herein are expressly incorporated herein by reference in their entirety into this disclosure, except to the extent they may directly contradict this disclosure. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A method comprising:
engaging a first edge region on a first surface of a substrate with a first support roller, wherein the first support roller is rotatable on a first end of a shaft, and wherein the substrate has a length substantially greater than a width thereof;
engaging a second edge region on the first surface of the substrate with a second support roller, wherein the second support roller is rotatable on a second end of the shaft opposite the first end thereof, and wherein a central region between the first roller and the second roller and comprising at least about 50% of a width of the substrate is free of support from a roller;
transporting the substrate over the first and the second support rollers;
repeating the following sequence of steps for a number of times sufficient to form a thin film on the substrate:
(a) exposing the substrate to a first precursor;
(b) supplying a reactive species to the substrate to react with the first precursor after exposing the substrate to the first precursor; wherein the thin film is formed as a reaction product of the first precursor with the reactive species; and
depositing a vapor on the thin film to form a coating on the thin film.

2. The method of claim 1, further comprising cooling the substrate before depositing the vapor on the thin film.

3. The method of claim 1, comprising heating the substrate before exposing the substrate to the first precursor.

4. The method of claim 1, wherein a second surface of the substrate opposite the first surface thereof does not substantially contact the reactive species.

5. The method of claim 1, wherein depositing the vapor on the thin film occurs before the thin film contacts a solid surface covering more than 50% of the width of the substrate.

6. The method of claim 1, wherein the thin film has a thickness of 1 nm to 100 nm.

7. The method of claim 1, wherein the repeating step further comprises (c) after step (b), exposing the substrate to a second precursor and (d) supplying a reactive species to the substrate after exposing the substrate to the second precursor.

8. The method of claim 1, further comprising orienting at least one of the support rollers at an angle relative to the direction of motion of the substrate.

9. The method of claim 1, wherein the reactive species is generated by applying energy to a chemical compound.

10. The method of claim 1, wherein the reactive species is generated by introducing a chemical compound into a plasma.

11. The method of claim 1, wherein the thin film is deposited by atomic layer deposition.

12. The method of claim 11, further comprising depositing a vapor on the substrate to form a coating on the first surface of the substrate before the thin film is deposited.

13. The method of claim 1, further comprising pretreating the first surface of the substrate by supplying a plasma before depositing the vapor on the substrate.

14. The method of claim 1, further comprising curing the coating on the thin film or the first surface of the substrate.

15. A system, comprising,
a first zone into which a first precursor is introduced;
a second zone into which a second precursor is introduced;
a third zone between the first zone and the second zone and in which a reactive species is generated;
a substrate transport mechanism, comprising: at least two support rollers contacting a single major surface of the substrate, wherein the substrate has a first and a second edge, the support rollers comprising:
a first support roller contacting a first edge region of the substrate, and
a second support roller contacting a second edge region of the substrate,
wherein the substrate comprises an un-contacted region between the first and the second support roller comprising at least about 50% of the width of the substrate; and
a vapor processing system comprising a vapor source for producing a vapor.

16. The system of claim 15, further comprising a heating system to heat the substrate.

17. The system of claim 15, further comprising a cooling system to cool the substrate.

18. The system of claim 15, further comprising a curing source configured for initiating polymerization of a liquid monomer or a liquid oligomer deposited from the vapor onto the substrate.

19. The system of claim 15, further comprising a free radical generator for supplying a reactive species to the third zone.

20. The system of claim 15, further comprising an idler roller to support the substrate during a change in a direction of motion of the substrate.
